(19) United States
(12) Patent Application Publication
(10) Pub. No.: US 2026/0161077 A1
(43) Pub. Date: Jun. 11, 2026

(54) PHOTOSENSITIVE RESIN COMPOSITION, PHOTOSENSITIVE ELEMENT, AND METHOD FOR PRODUCING WIRING BOARD

(71) Applicant: Resonac Corporation, Minato-ku, Tokyo (JP)

(72) Inventors: Akiko TAKEDA, Minato-ku, Tokyo (JP); Yusaku WATANABE, Minato-ku, Tokyo (JP)

(21) Appl. No.: 18/857,995

(22) PCT Filed: Aug. 30, 2023
(86) PCT No.: PCT/JP2023/031612

§ 371 Date: Oct. 18, 2024

(30) Foreign Application Priority Data
Dec. 26, 2022 (JP) 2022-208362

(51) Int. Cl. G03F 7/033; G03F 7/031

(52) U.S. Cl. CPC G03F 7/033; G03F 7/031

(57) ABSTRACT

A photosensitive resin composition according to the present disclosure, contains a binder polymer, a photopolymerizable compound, a photopolymerization initiator, and a sensitizer, in which the binder polymer includes a polymer having a styrene compound and aryl (meth)acrylate as a monomer unit, the photopolymerizable compound includes a polyfunctional monomer having two or more reactive groups causing a reaction by radicals and 8 to 16 oxyethylene groups, and a content of the polyfunctional monomer is 96% by mass or more, on the basis of a total amount of the photopolymerizable compound.

### TECHNICAL FIELD

The present disclosure relates to a photosensitive resin composition, a photosensitive element, and a method for producing a wiring board.

### BACKGROUND ART

In the production of a stacked body that can be used as a wiring board, a resist pattern is formed in order to obtain desired wiring. The resist pattern can be formed by exposing and developing a photosensitive resin layer obtained by using a photosensitive resin composition. As the photosensitive resin composition, various compositions are considered.

For example, a photosensitive resin composition containing an anthracene derivative is described in Patent Literature 1.

### CITATION LIST

### Patent Literature

Patent Literature 1: WO 2007/004619 A1

### SUMMARY OF INVENTION

### Technical Problem

A cured product pattern used as the resist pattern, for example, is formed by photocuring (exposing) a photosensitive layer disposed on a base material, and then, developing and removing an uncured portion (an unexposed portion) of the photosensitive layer. Then, a portion of the base material in which the cured product pattern is not formed is subjected to a plating treatment, and then, the cured product pattern is peeled (removed) to form a wiring pattern. In order to form a fine wiring layer, it is necessary to further increase the resolution of the resist pattern. In addition, in a case where the photosensitive layer after photocuring is brittle, the resist pattern may be broken or chipped during developing, and a yield when forming a fine wiring layer may decrease. Therefore, the photosensitive resin composition used to form a fine wiring layer is required to form the resist pattern that is excellent in the resolution and has an excellent shape.

An object of one aspect of the present disclosure is to provide a photosensitive resin composition capable of forming a resist pattern that is excellent in a resolution and has an excellent shape. An object of another aspect of the present disclosure is to provide a photosensitive element and a method for producing a wiring board using the photosensitive resin composition.

### Solution to Problem

The present disclosure provides a photosensitive resin composition, a photosensitive element, and a method for producing a wiring board described below.
[1] A photosensitive resin composition, containing a binder polymer, a photopolymerizable compound, a photopolymerization initiator, and a sensitizer, in which the binder polymer includes a polymer having a styrene compound and aryl (meth)acrylate as a monomer unit, the photopolymerizable compound includes a polyfunctional monomer having two or more reactive groups causing a reaction by radicals and 8 to 16 oxyethylene groups, and a content of the polyfunctional monomer is 96% by mass or more, on the basis of a total amount of the photopolymerizable compound.
[2] The photosensitive resin composition according to [1] described above, in which a molecular weight of the polyfunctional monomer is 600 to 1200.
[3] The photosensitive resin composition according to [1] or [2] described above, in which the polyfunctional monomer further has a bisphenol A skeleton or a ditrimethylol propane skeleton.
[4] The photosensitive resin composition according to any one of [1] to [3] described above, in which the binder polymer further has hydroxyalkyl (meth)acrylate as a monomer unit.
[5] The photosensitive resin composition according to any one of [1] to [4] described above, in which the sensitizer includes a dialkyl aminobenzophenone compound or an anthracene compound.
[6] A photosensitive element, including: a support; and a photosensitive layer formed on the support by using the photosensitive resin composition according to any one of [1] to [5] described above.
[7] A method for producing a wiring board, including: a step of providing a photosensitive layer on a substrate by using the photosensitive resin composition according to any one of [1] to [5] described above; a step of photocuring a part of the photosensitive layer; a step of removing an uncured portion of the photosensitive layer to form a resist pattern; and a step of forming a wiring layer in a portion of the substrate in which the resist pattern is not formed.
[8] A method for producing a wiring board, including a step of providing a photosensitive layer on a substrate by using the photosensitive element according to [6] described above; a step of photocuring a part of the photosensitive layer; a step of removing an uncured portion of the photosensitive layer to form a resist pattern; and a step of forming a wiring layer in a portion of the substrate in which the resist pattern is not formed.

### Advantageous Effects of Invention

According to one aspect of the present disclosure, it is possible to provide the photosensitive resin composition capable of forming the resist pattern that is excellent in the resolution and has an excellent shape. According to another aspect of the present disclosure, it is possible to provide the photosensitive element and the method for producing a wiring board using the photosensitive resin composition.

### BRIEF DESCRIPTION OF DRAWINGS

FIG. 1 is a schematic cross-sectional view illustrating a photosensitive element according to one embodiment.

FIG. 2 is a schematic view illustrating a method for producing a wiring board according to one embodiment.

### DESCRIPTION OF EMBODIMENTS

Hereinafter, an embodiment of the present disclosure will be described in detail.

Hereinafter, a preferred embodiment of the present disclosure will be described in detail with reference to the drawings as necessary. In the following embodiment, it is obvious that constituents (also including element steps and the like) are not necessarily essential except when particularly stated or when considered as apparently essential in principle. The same applies to numerical values and ranges, which is not to be construed as unduly limiting the present disclosure.

In this specification, the term “step” includes not only an independent step but also a step that is not explicitly distinguishable from other steps insofar as a desired function of the step is attained. The term “layer” includes not only a structure in which a layer is formed on the entire surface but also a structure in which a layer is formed on a part of the surface when observed as a plan view.

A numerical range of “A or more” indicates A and a range greater than A. A numerical range of “A or less” indicates A and a range less than A. A numerical range represented by using “to” indicates a range including numerical values described before and after “to” as the minimum value and the maximum value, respectively. In numerical ranges described in stages in this specification, the upper limit value or the lower limit value of a numerical range in a certain stage can be arbitrarily combined with the upper limit value or the lower limit value of a numerical range in the other stage. In the numerical range described in this specification, the upper limit value or the lower limit value of the numerical range may be replaced with values described in Examples. “A or B” may include either A or B, or may include both thereof. Only one type of materials exemplified in this specification can be used alone, or two or more types thereof can be used in combination, unless otherwise specified.

In this specification, a “(meth)acrylic acid” indicates at least one of an “acrylic acid” and a “methacrylic acid” corresponding thereto. The same also applies to other similar expressions such as (meth)acrylate. An “alkyl group” may be a linear, branched, or cyclic alkyl group, unless otherwise specified. A “(poly)oxyethylene group” indicates an oxyethylene group, or a polyoxyethylene group in which two or more ethylene groups are linked by an ether bond. A “(poly)oxypropylene group” indicates an oxypropylene group, or a polyoxypropylene group in which two or more propylene groups are linked by an ether bond. “EO-modified” indicates a compound having a (poly)oxyethylene group. “PO-modified” indicates a compound having a (poly)oxypropylene group. “EO/PO-modified” indicates a compound having a (poly)oxyethylene group and/or a (poly)oxypropylene group.

In this specification, in a case where there are a plurality of substances corresponding to each component in a composition, the amount of each component in the composition indicates the total amount of the plurality of substances in the composition, unless otherwise specified. In this specification, a “solid content” indicates a non-volatile content excluding a volatile substance (water, a solvent, or the like) in a photosensitive resin composition. That is, the “solid content” indicates a component other than the solvent, which remains without being volatilized in the drying of the photosensitive resin composition described below, and also includes a component in the form of a liquid, syrup, or a wax at a room temperature (25° C.).

### [Photosensitive Resin Composition]

A photosensitive resin composition according to this embodiment contains Component (A): a binder polymer, Component (B): a photopolymerizable compound, Component (C): a photopolymerization initiator, and Component (D): a sensitizer. Here, the component (A) includes a polymer (a) having a styrene compound and aryl (meth)acrylate as a monomer unit, the component (B) includes a polyfunctional monomer having two or more reactive groups causing a reaction by radicals and 8 to 16 oxyethylene groups, and the content of the polyfunctional monomer is 96% by mass or more, on the basis of the total amount of the photopolymerizable compound. The photosensitive resin composition according to this embodiment, for example, can be used as a negative photosensitive resin composition. The photosensitive resin composition, as necessary, may further contain Component (E): a polymerization inhibitor or other components. Hereinafter, each component will be described.

### (Component (A): Binder Polymer)

The photosensitive resin composition contains the binder polymer as the component (A). The component (A) may have a polymerizable monomer as the monomer unit (a structural unit), and for example, can be obtained by the radical polymerization of the polymerizable monomer.

The component (A), from the viewpoint of forming a resist pattern excellent in a resolution, has the styrene compound as the monomer unit. Examples of the styrene compound include styrene, a styrene derivative, and the like. Examples of the styrene derivative include vinyl toluene and α-methyl styrene.

The content of the styrene compound in the component (A), from the viewpoint of the resolution, may be 35% by mass or more, 40% by mass or more, 42% by mass or more, or 44% by mass or more, and from the viewpoint of a developing property, may be 70% by mass or less, 60% by mass or less, 58% by mass or less, or 55% by mass or less, on the basis of the total amount of the monomer unit configuring the component (A). From such a viewpoint, the content of the monomer unit of the styrene compound may be 35 to 70% by mass, 40 to 60% by mass, 42 to 58% by mass, or 44 to 55% by mass.

The component (A), from the viewpoint of forming the resist pattern excellent in the resolution, has the aryl (meth)acrylate as the monomer unit. Examples of the aryl (meth)acrylate include benzyl (meth)acrylate, phenyl (meth)acrylate, and naphthyl (meth)acrylate.

The content of the monomer unit of the aryl (meth)acrylate, from the viewpoint of the resolution, may be 5% by mass or more, 10% by mass or more, 15% by mass or more, or 18% by mass or more, and from the viewpoint of the resolution, may be 40% by mass or less, 30% by mass or less, 28% by mass or less, or 25% by mass or less, on the basis of the total amount of the monomer unit configuring the component (A). From such a viewpoint, the content of the monomer unit of the aryl (meth)acrylate may be 5 to 40% by mass, 10 to 30% by mass, 15 to 28% by mass, or 18 to 25% by mass.

The component (A), from the viewpoint of increasing an alkali developing property, may have the (meth)acrylic acid as the monomer unit. The content of the (meth)acrylic acid in the component (A) may be 10% by mass or more, 15% by mass or more, 20% by mass or more, or 25% by mass or more, and may be 50% by mass or less, 45% by mass or less, 40% by mass or less, 35% by mass or less, or 30% by mass or less, on the basis of the total amount of the monomer unit configuring the component (A).

The component (A), from the viewpoint of increasing the alkali developing property, may have the hydroxyalkyl (meth)acrylate as the monomer unit. Examples of the hydroxyalkyl (meth)acrylate include hydroxymethyl (meth)acrylate, (meth)acrylate, hydroxyethyl hydroxypropyl (meth)acrylate, hydroxybutyl (meth)acrylate, hydroxypentyl (meth)acrylate, and hydroxyhexyl (meth)acrylate.

The content of the hydroxyalkyl (meth)acrylate in the component (A) may be 0.5% by mass or more, 1.0% by mass or more, or 1.5% by mass or more, and may be 20% by mass or less, 10% by mass or less, or 5% by mass or less, on the basis of the total amount of the monomer unit configuring the component (A).

The component (A) may further have structural units derived from other monomers in addition to the monomers described above. Examples of the other monomer include alkyl (meth)acrylate, ethers of vinyl alcohol (such as vinyl-n-butyl ether), (meth)acrylonitrile, a maleic acid, a maleic anhydride, maleic acid monoester (such as monomethyl maleate, monoethyl maleate, and monoisopropyl maleate), a fumaric acid, a cinnamic acid, an α-cyanocinnamic acid, an itaconic acid, a crotonic acid, and a propiolic acid.

As the other monomer, from the viewpoint of improving the alkali developing property and peelability, the alkyl (meth)acrylate may be preferable. The alkyl group of the alkyl (meth)acrylate, for example, may be a methyl group, an ethyl group, a propyl group, a butyl group, a pentyl group, a hexyl group, a heptyl group, an octyl group, a nonyl group, a decyl group, an undecyl group, a dodecyl group, or a structural isomer thereof, and from the viewpoint of further improving the peelability, may be an alkyl group having 1 to 4 carbon atoms.

The acid value of the component (A), from the viewpoint of enabling suitable development, may be 100 mgKOH/g or more, 120 mgKOH/g or more, 140 mgKOH/g or more, 150 mgKOH/g or more, or 160 mgKOH/g or more, and from the viewpoint of improving the cohesiveness (the developer resistance) of a cured product of the photosensitive resin composition, may be 250 mgKOH/g or less, 240 mgKOH/g or less, 230 mgKOH/g or less, 200 mgKOH/g or less, or 190 mgKOH/g or less. The acid value of the component (A) can be adjusted by the content of the structural unit configuring the component (A) (for example, a structural unit derived from a (meth)acrylic acid). The acid value can be measured by a method described in Examples.

The weight average molecular weight (Mw) of the component (A), from the viewpoint of excellent cohesiveness (developer resistance) of the cured product of the photosensitive resin composition, may be 10000 or more, 20000 or more, 25000 or more, or 30000 or more, and from the viewpoint of enabling suitable development, may be 100000 or less, 80000 or less, 60000 or less, 50000 or less, or 40000 or less. The number average molecular weight (Mn) of the component (A), from the viewpoint of easily shortening the peeling time of a cured portion, may be 5000 or more, 10000 or more, 12000 or more, or 15000 or more, and may be 35000 or less, 30000 or less, 25000 or less, or 22000 or less. The degree (Mw/Mn) of dispersion of the component (A), for example, may be 1.0 or more, 1.5 or more, or 2.0 or more, and from the viewpoint of further improving the cohesiveness and the resolution, may be 3.0 or less, 2.8 or less, or 2.5 or less.

The weight average molecular weight and the degree of dispersion, for example, can be measured by gel permeation chromatography (GPC) using a calibration curve of standard polystyrene. More specifically, measurement can be performed in a condition described in Examples. Note that in a case where it is difficult to measure the weight average molecular weight of a low-molecular-weight compound by the measurement method described above, the molecular weight can also be measured by other methods, and the average thereof can be calculated.

The content of the component (A), from the viewpoint of being excellent in the moldability of a film, may be 20% by mass or more, 30% by mass or more, or 40% by mass or more, and from the viewpoint of being more excellent in a sensitivity and the resolution, may be 90% by mass or less, 80% by mass or less, or 65% by mass or less, on the basis of the total solid content of the photosensitive resin composition.

The content of the component (A), from the viewpoint of being excellent in the moldability of the film, may be 30 parts by mass or more, 35 parts by mass or more, or 40 parts by mass or more, and from the viewpoint of further improving the sensitivity and the resolution, may be 70 parts by mass or less, 65 parts by mass or less, or 60 parts by mass or less, with respect to 100 parts by mass of the total amount of the component (A) and the component (B).

### (Component (B): Photopolymerizable Compound)

The photosensitive resin composition contains the photopolymerizable compound as the component (B). By the photosensitive resin composition according to this embodiment containing 96% by mass or more of the polyfunctional monomer having two or more reactive groups causing a reaction by radicals and 8 to 16 oxyethylene groups, on the basis of the total amount of the component (B), it is possible to form the resist pattern that is excellent in the resolution and has an excellent shape with no breakage and chip.

The number of reactive groups in the polyfunctional monomer, from the viewpoint of being more excellent in the resolution, may be 2 to 6, 2 to 5, or 2 to 4. Examples of the reactive group include a group having an ethylenically unsaturated bond, such as a (meth)acryloyl group. The number of oxyethylene groups in the polyfunctional monomer, from the viewpoint of further suppressing the breakage and chip of the resist pattern, may be 8 to 14, 8 to 12, or 10 to 12. The polyfunctional monomer may not have an oxypropylene group.

The molecular weight of the polyfunctional monomer, from the viewpoint of increasing the toughness of the resist pattern, may be 600 to 1200, 700 to 1150, 750 to 1100, or 780 to 1000.

The polyfunctional monomer, from the viewpoint of further improving the resolution, may further have a bisphenol A skeleton or a ditrimethylol propane skeleton. The polyfunctional monomer having a bisphenol A skeleton may be a (meth)acrylic acid compound having a bisphenol A skeleton. The polyfunctional monomer having a ditrimethylol propane skeleton may be a (meth)acrylic acid compound having a ditrimethylol propane skeleton. The polyfunctional monomer may include at least one of the (meth)acrylic acid compound having a bisphenol A skeleton and the (meth)acrylic acid compound having a ditrimethylol propane skeleton, or may have both thereof.

Examples of the di(meth)acrylic acid compound having a bisphenol A skeleton include EO-modified bisphenol A di(meth)acrylate (EO Group: 8 to 16). Examples of the (meth)acrylic acid compound having a ditrimethylol propane skeleton include EO-modified ditrimethylol propane tetra(meth)acrylate (EO Group: 8 to 16).

The content of the polyfunctional monomer, from the viewpoint of further suppressing the breakage and chip of the resist pattern, is preferably 97% by mass or more, more preferably 98% by mass or more, and even more preferably 99% by mass or more, and may be 100% by mass, on the basis of the total amount of the component (B). That is, the component (B) may not include a monofunctional monomer.

The content of the polyfunctional monomer, from the viewpoint of further improving the sensitivity and the resolution, may be 30 to 60 parts by mass, 35 to 55 parts by mass, or 40 to 50 parts by mass, with respect to 100 parts by mass of the total amount of the component (A) and the component (B).

### (Component (C): Photopolymerization Initiator)

The photosensitive resin composition contains the photopolymerization initiator as the component (C). The component (C) is not particularly limited insofar as the component (B) can be polymerized, and can be suitably selected from photopolymerization initiators that are commonly used.

Examples of the component (C) include a hexaaryl biimidazole compound; aromatic ketone such as benzophenone, 2-benzyl-2-dimethyl amino-1-(4-morpholinophenyl)-1-butanone, 2-(dimethyl amino)-2-[(4-methyl phenyl)methyl]-1-[4-(4-morpholinyl)phenyl]-1-butanone, 4-(2-hydroxyethoxy)phenyl-2-(hydroxy-2-propyl) ketone, and 2-methyl-1-[4-(methyl thio)phenyl]-2-morpholino-propane-1; quinone such as alkyl anthraquinone; a benzoin ether compound such as benzoin alkyl ether; a benzoin compound such as benzoin and alkyl benzoin; a benzyl derivative such as benzyl dimethyl ketal; and a phosphine oxide compound such as bis(2,4,6-trimethyl benzoyl)-phenyl phosphine oxide, bis(2,6-dimethyl benzoyl)-2,4,4-trimethyl-pentyl phosphine oxide, and (2,4,6-trimethyl benzoyl) ethoxyphenyl phosphine oxide.

The component (C), from the viewpoint of easily obtaining excellent sensitivity, resolution, and cohesiveness, may include the hexaaryl biimidazole compound. The aryl group of the hexaaryl biimidazole compound may be a phenyl group or the like. A hydrogen atom bonded to the aryl group of the hexaaryl biimidazole compound may be substituted with a halogen atom (such as a chlorine atom).

The hexaaryl biimidazole compound may be a 2,4,5-triaryl imidazole dimer. Examples of the 2,4,5-triaryl imidazole dimer include a 2-(o-chlorophenyl)-4,5-diphenyl imidazole dimer, a 2-(o-chlorophenyl)-4,5-bis-(m-methoxyphenyl) imidazole dimer, and a 2-(p-methoxyphenyl)-4,5-diphenyl imidazole dimer. As the hexaaryl biimidazole compound, from the viewpoint of easily obtaining excellent sensitivity, resolution, and cohesiveness, the 2-(o-chlorophenyl)-4,5-diphenyl imidazole dimer is preferable, and 2,2-bis(o-chlorophenyl)-4,5-4′,5′-tetraphenyl-1,2′biimidazole is more preferable.

The content of the hexaaryl biimidazole compound, from the viewpoint of easily obtaining excellent sensitivity, resolution, and cohesiveness, may be 90% by mass or more, 95% by mass or more, or 99% by mass or more, on the basis of the total amount of the component (C). The component (C) may consist of only the hexaaryl biimidazole compound.

The content of the component (C) may be 1.0 to 20 parts by mass, 2.0 to 15 parts by mass, 3.0 to 10 parts by mass, or 4.0 to 8.0 parts by mass, with respect to 100 parts by mass of the total amount of the component (A) and the component (B). In a case where the content of the component (C) is in such a range, it is easy to improve both of a photosensitivity and the resolution in a balanced way.

### (Component (D): Sensitizer)

By the photosensitive resin composition containing the component (D), it is possible to effectively utilize the absorption wavelength of an active ray used for exposure.

Examples of the component (D) include a dialkyl aminobenzophenone compound, a pyrazoline compound, an anthracene compound, a coumarin compound, a xanthone compound, a thioxanthone compound, an oxazole compound, a benzoxazole compound, a thiazole compound, a benzothiazole compound, a triazole compound, a stilbene compound, a triazine compound, a thiophene compound, a naphthal imide compound, a triaryl amine compound, and an aminoacridine compound.

Examples of the dialkyl aminobenzophenone compound include 4,4′-bis(diethyl amino)benzophenone and 4-methoxy-4′-dimethyl aminobenzophenone.

Examples of the pyrazoline compound include 1-phenyl-3-(4-methoxystyryl)-5-(4-methoxyphenyl) pyrazoline, 1-phenyl-3-(4-tert-butyl styryl)-5-(4-tert-butyl phenyl) pyrazoline, and 1-phenyl-3-biphenyl-5-(4-tert-butyl phenyl) pyrazoline.

Examples of the coumarin compound include 3-benzoyl-7-diethyl aminocoumarin, 7-diethyl amino-4-methyl coumarin, 3,3′-carbonyl bis(7-diethyl aminocoumarin), and 2,3,6,7-tetrahydro-9-methyl-1H,5H,11H-[1]benzopyrano[6,7,8-ij]quinolizin-11-one.

Examples of the anthracene compound include 9,10-dimethoxyanthracene, 9,10-diethoxyanthracene, 9,10-dipropoxyanthracene, 9,10-dibutoxyanthracene, and 9,10-dipentoxyanthracene.

The component (D), from the viewpoint of further improving the resolution, may include the dialkyl aminobenzophenone compound or the anthracene compound. From the viewpoint of further improving the resolution and the cohesiveness, it is more preferable that the component (D) includes the 9,10-diethoxyanthracene, 9,10-propoxyanthracene, or the 9,10-dibutoxyanthracene.

The content of the component (D), from the viewpoint of further improving the sensitivity, the cohesiveness, and the resolution, may be 0.01 to 1.5 parts by mass, 0.02 to 1.2 parts by mass, or 0.03 to 1.0 parts by mass, with respect to 100 parts by mass of the total amount of the component (A) and the component (B).

### (Component (E): Polymerization Inhibitor)

The photosensitive resin composition, from the viewpoint of suppressing polymerization in an unexposed portion when forming the resist pattern, and further improving the resolution, may further contain Component (E): the polymerization inhibitor. Examples of the polymerization inhibitor include 4-tert-butyl catechol and 4-hydroxy-2,2,6,6-tetramethyl piperidine-N-oxyl.

The content of the component (E), from the viewpoint of the sensitivity and the resolution, may be 0.001 parts by mass or more, 0.005 parts by mass or more, or 0.01 parts by mass or more, and from the viewpoint of the sensitivity and the cohesiveness, may be 0.10 parts by mass or less, 0.08 parts by mass or less, or 0.05 parts by mass or less, with respect to 100 parts by mass of the total amount of the component (A) and the component (B).

### (Other Components)

The photosensitive resin composition may further contain one type or two or more types of other components in addition to the components described above. Examples of the other component include a hydrogen donor (such as bis[4-(dimethyl amino)phenyl] methane, bis[4-(diethyl amino)phenyl]methane, and N-phenyl glycine), a colorant (such as malachite green), tribromophenyl sulfone, a photocolor former (such as Leuco crystal violet), a thermal color formation inhibitor, a plasticizer (such as p-toluene sulfone amide), a pigment, a filling agent, an antifoaming agent, a flame retarder, a stabilizer, a cohesiveness imparting agent, a leveling agent, a peeling accelerator, an antioxidant, a fragrance, an imaging agent, and a thermal cross-linking agent. The content of the other component may be 0.005 parts by mass or more, or 0.01 parts by mass or more, and may be 20 parts by mass or less, or 10 parts by mass or less, with respect to 100 parts by mass of the total amount of the component (A) and the component (B).

The photosensitive resin composition, from the viewpoint of adjusting a viscosity, may further contain one type or two or more types of organic solvents. Examples of the organic solvent include methanol, ethanol, acetone, methyl ethyl ketone, methyl cellosolve, ethyl cellosolve, toluene, N,N-dimethyl formamide, and propylene glycol monomethyl ether. By dissolving the components (A) to (D) in the organic solvent, the photosensitive resin composition, for example, can be used as a solution (hereinafter, referred to as a “coating liquid”) with a solid content (a non-volatile content) of approximately 30 to 60% by mass. Note that the solid content indicates the remaining components after removing volatile components from the solution of the photosensitive resin composition.

The photosensitive resin composition can be preferably used to form the resist pattern, and can be particularly preferably used for a method for producing a wiring board described below.

### [Photosensitive Element]

A photosensitive element according to this embodiment includes a support, and a photosensitive layer formed on the support by the photosensitive resin composition described above. The photosensitive element may further include a protective layer on the photosensitive layer.

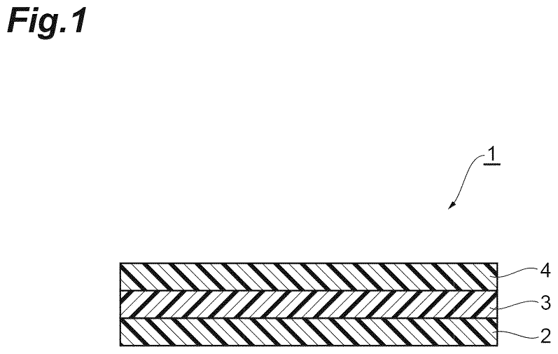

FIG. 1 is a schematic cross-sectional view illustrating a photosensitive element according to one embodiment. A photosensitive element 1, as illustrated in FIG. 1, includes a support 2, a photosensitive layer 3 provided on the support 2, and a protective layer 4 provided on the photosensitive layer 3 on a side opposite to the support 2.

As the support, a polymer film having heat resistance and solvent resistance can be used. Examples of the support include a polyester film such as a polyethylene terephthalate film (PET), polybutylene terephthalate (PBT), and polyethylene-2,6-naphthalate (PEN), and a polyolefin film such as a polyethylene film and a polypropylene film.

The haze of the support may be 0.01 to 5.0%, 0.01 to 1.5%, 0.01 to 1.0%, or 0.01 to 0.5%. The haze can be measured by using a commercially available haze meter (a turbidimeter), on the basis of a method defined in JIS K7105. The haze, for example, can be measured with a commercially available turbidimeter such as NDH-5000 (manufactured by NIPPON DENSHOKU INDUSTRIES CO., LTD., product name).

The thickness of the support, from the viewpoint of easily suppressing a damage to the support when peeling the support from the photosensitive layer, may be 1 μm or more, 5 μm or more, or 10 μm or more. The thickness of the support, from the viewpoint of preferably facilitating exposure when performing the exposure via the support, may be 100 μm or less, 50 μm or less, 30 μm or less, or 20 μm or less.

The protective layer may be a polymer film having heat resistance and solvent resistance, and for example, a polyolefin film such as a polyethylene film and a polypropylene film can be used. In particular, by using the polyethylene film as the protective layer, it is possible to suppress the winding slippage of the photosensitive element, and since static electricity is less likely to be generated when peeling the protective layer from the photosensitive layer, it is possible to suppress a damage to the photosensitive layer.

The thickness of the protective layer, from the viewpoint of easily suppressing a damage to the protective layer when laminating the photosensitive layer and the support on a substrate while peeling the protective layer, may be 1 μm or more, 5 μm or more, 10 μm or more, or 15 μm or more. From the viewpoint of easily improving productivity, the thickness may be 100 μm or less, 50 μm or less, 40 μm or less, or 30 μm or less.

The photosensitive layer consists of the photosensitive resin composition described above. The thickness of the photosensitive layer after drying (after volatilizing the organic solvent in a case where the photosensitive resin composition contains the organic solvent), from the viewpoint of facilitating coating and improving the productivity, may be 1 μm or more, 5 μm or more, or 10 μm or more, and from the viewpoint of further improving the cohesiveness and the resolution, may be 100 μm or less, 50 μm or less, 40 μm or less, or 30 μm or less.

The photosensitive element 1, for example, can be obtained as described below. First, the photosensitive layer 3 is formed on the support 2. The photosensitive layer 3, for example, can be formed by applying the photosensitive resin composition containing the organic solvent to form a coated layer, and drying the coated layer. Next, the protective layer 4 is formed on the surface of the photosensitive layer 3 on a side opposite to the support 2.

The coated layer, for example, is formed by a known method such as roll coating, comma coating, gravure coating, air knife coating, die coating, and bar coating. The coated layer is dried such that the amount of organic solvent remaining in the photosensitive layer 3, for example, is 2% by mass or less, and specifically, the coated layer is dried, for example, at 70 to 150° C. for approximately 5 to 30 minutes.

The thickness of the photosensitive layer after drying (after volatilizing the organic solvent in a case where the photosensitive resin composition contains the organic solvent), from the viewpoint of facilitating the coating and improving the productivity, may be 1 μm or more, 5 μm or more, or 10 μm or more, from the viewpoint of further improving the cohesiveness and the resolution, may be 100 μm or less, 50 μm or less, or 40 μm or less.

In another embodiment, the photosensitive element may further include other layers such as a cushion layer, a bonding adhesive layer, a light absorption layer, and a gas barrier layer.

The photosensitive element 1, for example, may be in the shape of a sheet, or may be in the form of a photosensitive element roll wound around a winding stem into the shape of a roll. In the photosensitive element roll, the photosensitive element 1 is preferably wound such that the support 2 is on the outside. The winding stem, for example, is formed of polyethylene, polypropylene, polystyrene, polyvinyl chloride, an acrylonitrile-butadiene-styrene copolymer, and the like. On the end surface of the photosensitive element roll, from the viewpoint of protecting the end surface, an end surface separator may be provided, and from the viewpoint of edge fusion resistance, a moisture-proof end surface separator may be provided. The photosensitive element, for example, may be wrapped with a black sheet having low moisture permeability.

The photosensitive element according to this embodiment can be preferably used to form the resist pattern, and can be particularly preferably used for the method for producing a wiring board described below.

### [Method for Forming Resist Pattern]

A method for forming a resist pattern according to this embodiment includes a step of disposing a photosensitive layer and a support on a substrate in this order from the substrate side by using the photosensitive element described above (a photosensitive layer forming step), a step of exposing the photosensitive layer with an active ray via the support (an exposing step), and a step of peeling the support, and then, removing an uncured portion of the photosensitive layer from the substrate (a developing step), and as necessary, may include other steps. Note that the resist pattern can also be referred to as a photocured product pattern of the photosensitive resin composition, and can also be referred to as a relief pattern.

### (Photosensitive Layer Forming Step)

In the photosensitive layer forming step, the photosensitive layer is formed on the substrate by using the photosensitive element. The substrate is not particularly limited, and in general, a substrate for forming a circuit, including an insulating layer, and a conductor layer formed on the insulating layer, a die pad (a base material for a lead frame) such as an alloy base material, or the like can be used.

As a method for forming the photosensitive layer on the substrate, for example, the photosensitive layer can be formed on the substrate by removing a protective layer from the photosensitive element, and then, crimping the photosensitive layer of the photosensitive element to the substrate while heating the photosensitive layer. Accordingly, a stacked body including the substrate, the photosensitive layer, and the support in this order is obtained.

The photosensitive layer forming step, from the viewpoint of the cohesiveness and followability, may be performed under a reduced pressure. Heating during crimping may be performed at a temperature of 70 to 130° C., and crimping may be performed at a pressure of 0.1 to 1.0 MPa (1 to 10 kgf/cm²), but such a condition, as necessary, can be suitably selected. Note that in a case where the photosensitive layer of the photosensitive element is heated to 70 to 130° C., it is not necessary to perform in advance a preheat treatment on the substrate, but in order to further improve the cohesiveness and the followability, the preheat treatment can also be performed on the substrate.

### (Exposing Step)

In the exposing step, the photosensitive layer is exposed with the active ray via the support. Accordingly, an exposed portion irradiated with the active ray is photocured to form a photocured portion (a latent image).

As an exposure method, a known exposure method can be applied, and examples thereof include a method (a mask exposure method) for applying an active ray into the shape of an image via a negative or positive mask pattern, referred to as artwork, a laser direct imaging (LDI) exposure method, a method (a projection exposure method) for applying an active ray projected with a photomask image into the shape of an image via a lens, or the like. Among them, from the viewpoint of being excellent in the resolution, the LDI exposure method or the projection exposure method may be used. The projection exposure method can also be referred to as an exposure method using an active ray with an attenuated energy amount.

A light source of the active ray is not particularly limited insofar as the light source is a known light source that is commonly used, and for example, a light source for effectively emitting an ultraviolet ray, such as a carbon arc lamp, a mercury vapor arc lamp, a super high-pressure mercury lamp, a high-pressure mercury lamp, a xenon lamp, gas laser such as argon laser, solid-state laser such as YAG laser, and semiconductor laser such as gallium nitride-based bruise blue laser, can be used. Among them, from the viewpoint of improving the resolution and an alignment property in a balanced way, a light source capable of emitting an i-line monochromatic light with an exposure wavelength of 365 nm, a light source capable of emitting an h-line monochromatic light with an exposure wavelength of 405 nm, or a light source capable of emitting an active ray with the exposure wavelength of an ihg-mixed line may be used, and it is preferable to use the light source capable of emitting the i-line monochromatic light with an exposure wavelength of 365 nm or the h-line monochromatic light with an exposure wavelength of 405 nm. Examples of the light source capable of emitting the i-line monochromatic light with an exposure wavelength of 365 nm include a super high-pressure mercury lamp and the like. Examples of the light source capable of emitting the h-line monochromatic light with an exposure wavelength of 405 nm include a bruise blue laser diode with a wavelength of 405 nm.

(Heat Treatment Step after Exposure)

In the method for forming a resist pattern according to this embodiment, from the viewpoint of improving the cohesiveness, post exposure bake (PEB) may be performed after the exposing step and before the developing step. A temperature when performing PEB may be 50 to 100° C. As a heater, a hot plate, a box-type dryer, a heat roll, and the like may be used.

### (Developing Step)

In the developing step, the support is peeled, and then, the uncured portion of the photosensitive layer is removed from the substrate. By the developing step, the resist pattern consisting of the photocured portion obtained by photocuring the photosensitive layer is formed on the substrate. A development method may be wet development or dry development, and the wet development is preferable.

In the case of the wet development, the development can be performed by a known wet development method using a developer corresponding to the photosensitive resin composition. Examples of the wet development method include a dipping method, a puddle method, a high-pressure spray method, and a method using brushing, scrubbing, fluctuating immersion, and the like. The development may be performed by using only one type of the wet development method alone, or combining two or more types of methods.

The developer is suitably selected in accordance with the configuration of the photosensitive resin composition. Examples of the developer include an alkaline aqueous solution and an organic solvent developer.

As the developer, from the viewpoint of safety and stability, and excellent manipulativeness, the alkaline aqueous solution may be used. As the base of the alkaline aqueous solution, for example, alkali hydroxide such as a hydroxide of lithium, sodium, or potassium, alkali carbonate such as a carbonate or a bicarbonate of lithium, sodium, potassium, or ammonium, an alkali metallic phosphate such as potassium phosphate and sodium phosphate, an alkali metallic pyrophosphate such as sodium pyrophosphate and potassium pyrophosphate, sodium borate, sodium metasilicate, tetramethyl ammonium hydroxide, ethanol amine, ethylene diamine, diethylene triamine, 2-amino-2-hydroxymethyl-1,3-propane diol, 1,3-diamino-2-propanol, and morpholine are used.

As the alkaline aqueous solution, for example, 0.1 to 5% by mass of a sodium carbonate diluted solution, 0.1 to 5% by mass of a potassium carbonate diluted solution, 0.1 to 5% by mass of a sodium hydroxide diluted solution, 0.1 to 5% by mass of a sodium tetraborate diluted solution, and the like can be used. In addition, the pH of the alkaline aqueous solution used for development may be in a range of 9 to 11, and the temperature of the alkaline aqueous solution can be adjusted in accordance with the developing property of the photosensitive layer. In addition, in the alkaline aqueous solution, for example, a surface-active agent, an antifoaming agent, a small amount of organic solvent for accelerating development, and the like may be mixed.

Examples of the organic solvent used for the alkaline aqueous solution include 3-acetone alcohol, acetone, ethyl acetate, alkoxyethanol having an alkoxy group having 1 to 4 carbon atoms, ethyl alcohol, isopropyl alcohol, butyl alcohol, diethylene glycol monomethyl ether, diethylene glycol monoethyl ether, and diethylene glycol monobutyl ether.

Examples of the organic solvent used for the organic solvent developer include 1,1,1-trichloroethane, N-methyl-2-pyrrolidone, N,N-dimethyl formamide, cyclohexanone, methyl isobutyl ketone, and γ-butyrolactone. Such an organic solvent, from the viewpoint of preventing ignition, may be used as the organic solvent developer by adding water in a range of 1 to 20% by mass.

### (Other Steps)

The method for forming a resist pattern according to this embodiment, as necessary, may include a step of further curing the resist pattern by performing heating at 60 to 250° C. or exposure in an exposure amount of 0.2 to 10 J/cm², after removing the uncured portion in the developing step.

### [Method for Producing Wiring Board]

A method for producing a wiring board according to this embodiment includes a step of providing a photosensitive layer on a substrate by using the photosensitive resin composition or the photosensitive element described above, a step of photocuring a part of the photosensitive layer, a step of removing an uncured portion of the photosensitive layer to form a resist pattern, and a step of forming a wiring layer in a portion of the substrate in which the resist pattern is not formed.

A method for producing a printed wiring board according to this embodiment includes a step of performing an etching treatment or a plating treatment on a substrate on which the resist pattern is formed by the method for forming a resist pattern to form a conductor pattern, and as necessary, may include other steps such as a resist pattern removing step. By the method for forming a resist pattern using the photosensitive element, the method for producing a printed wiring board according to this embodiment can be preferably used to form the conductor pattern, and is particularly suitable for an application to a method for forming the conductor pattern by the plating treatment. Note that the conductor pattern can also be referred to as a circuit.

In the etching treatment, by using the resist pattern formed on the substrate including a conductor layer as a mask, the conductor layer of the substrate that is not covered with a resist is removed by etching to form the conductor pattern.

An etching treatment method is suitably selected in accordance with the conductor layer to be removed. Examples of an etching liquid include a copper (II) chloride solution, an iron (II) chloride solution, an alkali etching solution, a hydrogen peroxide-based etching liquid, and the like. From the viewpoint of an excellent etching factor, it is preferable to use the iron (II) chloride solution as the etching liquid.

In the plating treatment, by using the resist pattern formed on the substrate including the conductor layer as a mask, copper, solder, or the like is plated on the conductor layer of the substrate that is not covered with the resist. After the plating treatment, the resist is removed by removing the resist pattern described below, and the conductor layer covered with the resist is further etched to form the conductor pattern.

A plating treatment method may be an electrolytic plating treatment, or may be an electroless plating treatment, and examples thereof include copper plating such as copper sulfate plating and copper pyrophosphate plating, solder plating such as high throw solder plating, nickel plating such as Watts bath (nickel sulfate-nickel chloride) plating and nickel sulfamate plating, and gold plating such as hard gold plating and soft gold plating.

After the etching treatment or the plating treatment, the resist pattern on the substrate is removed. In the removal of the resist pattern, for example, the resist pattern can be peeled with an alkaline aqueous solution stronger than the alkaline aqueous solution used in the developing step. Examples of such a strong alkaline aqueous solution include 1 to 10% by mass of a sodium hydroxide aqueous solution, 1 to 10% by mass of a potassium hydroxide aqueous solution, and the like. Among them, 1 to 5% by mass of the sodium hydroxide aqueous solution or the potassium hydroxide aqueous solution may be used.

Examples of a method for removing the resist pattern include an immersion method and a spray method, and such methods may be used alone, or may be used together.

In a case where the resist pattern is removed after the plating treatment, by further etching the conductor layer covered with the resist by the etching treatment to form the conductor pattern, it is possible to provide a desired printed wiring board. In this case, the etching treatment method is suitably selected in accordance with the conductor layer to be removed. For example, the etching liquid described above can be applied.

The method for producing a printed wiring board according to this embodiment can be applied to not only the production of a single-layer printed wiring board, but also the production of a multilayer printed wiring board, and can also be applied to the production of a printed wiring board having a through hole with a small diameter.

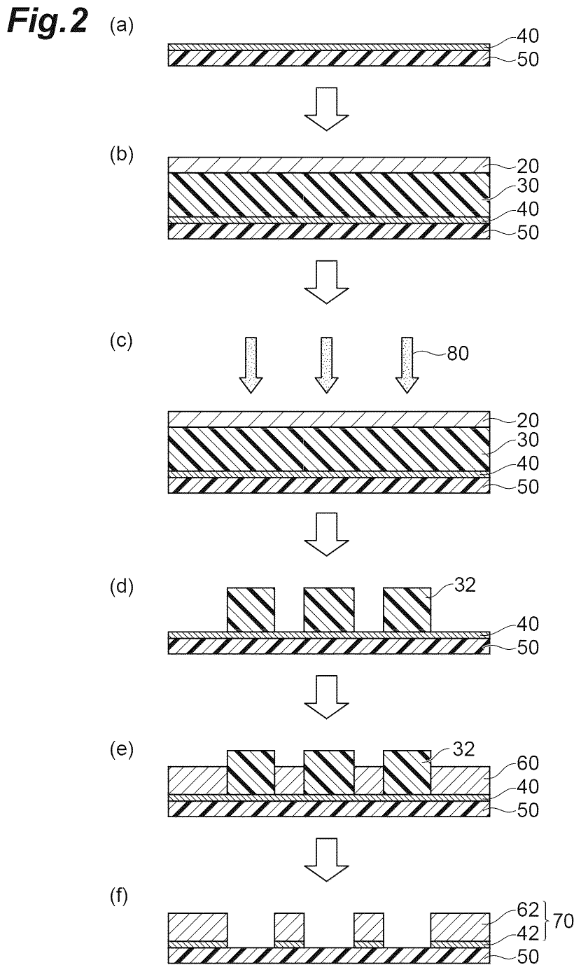

The method for producing a printed wiring board according to this embodiment can be preferably used to produce a high-density package substrate, and in particular, to produce a wiring board by a semi-additive method. Note that an example of a step of producing the wiring board by the semi-additive method is illustrated in FIG. 2.

In (a) of FIG. 2, a substrate (a substrate for forming a circuit) is prepared in which a conductor layer 40 is formed on an insulating layer 50. The conductor layer 40, for example, is a copper layer. In (b) of FIG. 2, by the photosensitive layer forming step, a photosensitive layer 30 and a support 20 are formed on the conductor layer 40 of the substrate. In (c) of FIG. 2, by the exposing step, an active ray 80 projected with a photomask image is applied onto the photosensitive layer 30 via the support 20 to form a photocured portion in the photosensitive layer 30. In (d) of FIG. 2, by the developing step, a region other than the photocured portion formed by the exposing step is removed from the substrate to form a resist pattern 32, which is the photocured portion, on the substrate.

In (e) of FIG. 2, by the plating treatment using the resist pattern 32, which is the photocured portion, as a mask, a plating layer 60 is formed on the conductor layer 40 of the substrate that is not covered with the resist. The conductor layer 40 and the plating layer 60 may contain the same material, or may contain different materials. In a case where the conductor layer 40 and the plating layer 60 contain the same material, the conductor layer 40 and the plating layer 60 may be integrated.

In (f) of FIG. 2, the resist pattern 32, which is the photocured portion, is peeled and removed by a strong alkaline aqueous solution. The strong alkaline aqueous solution, for example, may be 1 to 10% by mass of a sodium hydroxide aqueous solution, 1 to 10% by mass of a potassium hydroxide aqueous solution, and the like. Next, by a flash etching treatment, the conductor layer 40 masked with the resist pattern 32 is removed to form a conductor pattern 70 including a plating layer 62 after the etching treatment and a conductor layer 42 after the etching treatment. An etching liquid is suitably selected in accordance with the type of conductor layer 40, and for example, may be a copper (II) chloride solution, an iron (II) chloride solution, an alkali etching solution, a hydrogen peroxide etching liquid, and the like. Note that FIG. 2 illustrates a projection exposure method, but the resist pattern 32 may be formed by using a mask exposure method and an LDI exposure method together. By using the photosensitive element according to this embodiment, it is possible to produce the wiring board including a fine conductor layer (wiring layer).

A preferred embodiment of the present disclosure has been described, but the present disclosure is not limited to the embodiment described above.

### EXAMPLES

Hereinafter, the present disclosure will be described in more detail by Examples, but the present disclosure is not limited to such Examples.

### (Component (A): Binder Polymer)

Monomers shown in Table 1 were mixed with 0.9 parts by mass of azobisisobutyronitrile in a blending amount (Unit: parts by mass) shown in the same table to prepare a solution (a). 0.5 parts by mass of azobisisobutyronitrile was dissolved in 50 parts by mass of a mixed liquid (x) of 30 parts by mass of 1-methoxy-2-propanol and 20 parts by mass of toluene to prepare a solution (b). 500 parts by mass of the mixed liquid (x) (300 parts by mass of 1-methoxy-2-propanol and 200 parts by mass of toluene) was put in a flask provided with a stirrer, a reflux condenser, a thermometer, a dropping funnel, and a nitrogen gas introduction pipe, and then, stirred while blowing nitrogen gas into the flask, and heated to 80° C. The solution (a) was dropped into the mixed liquid in the flask at a constant dropping rate for 4 hours, and then, stirred at 80° C. for 2 hours. Next, the solution (b) was dropped into the solution in the flask at a constant dropping rate for 10 minutes, and then, the solution in the flask was stirred at 80° C. for 3 hours. Further, the solution in the flask was heated to 95° C. for 30 minutes, and kept at 95° C. for 2 hours, and then, stirring was stopped, and cooling was performed to a room temperature (25° C.) to obtain a solution of binder polymers A1 to A3. The non-volatile content (the solid content) of the solution of the binder polymers A1 to A3 was 49% by mass. The weight average molecular weight (Mw), the number average molecular weight (Mn), and the acid value of the binder polymers A1 to A3 are shown in Table 1.

Mw and Mn were derived by measurement using a gel permeation chromatography (GPC) in the following condition, and conversion using a calibration curve of standard polystyrene.

### (GPC Condition)

Pump: Hitachi L-6000 type (manufactured by Hitachi, Ltd., product name)
Column: Gelpack GL-R420, Gelpack GL-R430, Gelpack GL-R440 (all are manufactured by Showa Denko Materials Co., Ltd., product name)
Eluent: tetrahydrofuran
Measurement Temperature: 40° C.
Flow Rate: 2.05 mL/minute
Detector: Hitachi L-3300 type RI (manufactured by Hitachi, Ltd., product name)

The acid value was measured in the following procedure. First, 1 g of the binder polymer, which is a measurement target of the acid value, was weighed, and then, 30 g of acetone was added to the binder polymer to homogeneously dissolve the binder polymer, and a solution was obtained. Next, a suitable amount of phenolphthalein, which is an indicator, was added to the solution, and then, titration was performed by using 0.1 N of a potassium hydroxide (KOH) aqueous solution. The mass (Unit: mg) of KOH required to neutralize the acetone solution of the binder polymer was calculated to obtain the acid value.

TABLE 1

| Binder polymer | A1 | A2 | A3 |
|---|---|---|---|
| Methacrylic acid | 27 | 27 | 30 |
| Styrene | 45 | 50 | 30 |
| Benzyl methacrylate | 23 | 20 | — |
| Methyl methacrylate | 5 | — | 22 |
| Butyl methacrylate | — | — | 8 |
| 2-Hydroxyethyl | — | 3 | — |
| methacrylate | | | |
| Ethyl acrylate | — | — | 10 |
| Mw | 50000 | 35000 | 50000 |
| Mn | 21000 | 16000 | 21000 |
| Acid value (mgKOH/g) | 176 | 176 | 196 |

In order to prepare a photosensitive resin composition, the following components were prepared.

### (Component (B): Photopolymerizable Compound)

B1: EO-modified bisphenol A dimethacrylate (EO Group: 10 (Total Value), molecular weight: 804, manufactured by Showa Denko Materials Co., Ltd., product name “FA-321M”)
B2: EO-modified ditrimethylol propane tetramethacrylate (EO Group: 12 (Total Value), molecular weight: 1050, manufactured by TOHO Chemical Industry Co., Ltd.)
B3: EO-modified bisphenol A dimethacrylate (EO Group: 4 (Total Value), manufactured by SHIN-NAKAMURA CHEMICAL Co., Ltd., product name “BPE-200”)
B4: 2,2-bis(4-(methacryloxypolyethoxy)phenyl) propane (EO Group: 2.6 (Total Value), manufactured by kyoeisha Chemical Co., Ltd., product name “BP-2EM”)
B5: (PO) (EO) (PO)-modified dimethacrylate (EO Group: 6, and PO Group: 12 (Total Value), molecular weight: 1114, manufactured by Showa Denko Materials Co., Ltd., product name “FA-024M”)

### (Component (C): Photopolymerization Initiator)

BCIM: 2,2′-bis(o-chlorophenyl)-4,4′,5,5′-tetraphenyl-1,2′-biimidazole (manufactured by Hampford Research Inc.)

### (Component (D): Sensitizer)

D1: 4,4′-bis(diethyl amino)benzophenone (manufactured by Hodogaya Chemical Co., Ltd.)
D2: 9,10-dibutoxyanthracene (manufactured by AIR WATER PERFORMANCE CHEMICAL INC., product name “UVS-1331”)
D3: 9,10-diethoxyanthracene (manufactured by AIR WATER PERFORMANCE CHEMICAL INC., product name “UVS-1101”)
D4: 9,10-dipropoxyanthracene (manufactured by AIR WATER PERFORMANCE CHEMICAL INC., product name “UVS-1221”)

### (Component (E): Polymerization Inhibitor)

E1: 4-tert-butyl catechol (manufactured by DIC Corporation, product name “DIC-TBC”)
E2: 4-hydroxy-2,2,6,6-tetramethyl piperidine-N-oxyl (manufactured by ADEKA Corporation, product name “LA-7RD”)

### (Other Components)

LCV: Leuco crystal violet (manufactured by Yamada Chemical Co., Ltd.)
MKG: malachite green (manufactured by OSAKA ORGANIC CHEMICAL INDUSTRY LTD.)
SF-808H: a mixture of carboxybenzotriazole, 5-amino-1H-tetrazole, and methoxypropanol (manufactured by SANWA KASEI CORP.)

### Examples 1 to 3 and Comparative Examples 1 and 2

### (Photosensitive Resin Composition)

By mixing each component shown in Table 2 in a blending amount (parts by mass) shown in the same table, each photosensitive resin composition was prepared. Note that the blending amount (parts by mass) of the component (A) shown in Table 2 is the mass (the solid content) of a non-volatile content.

### (Photosensitive Element)

As a support, a polyethylene terephthalate film (manufactured by TORAY INDUSTRIES, INC., product name “FS-31”) with a thickness of 16 μm was prepared. The photosensitive resin composition was applied onto the support, and then, sequentially dried with a hot-air convection dryer at 80° C. and 120° C. to form a photosensitive layer (Thickness after Drying: 25 μm). As a protective layer, a polyethylene film (manufactured by TAMAPOLY CO., LTD., product name “NF-15”) with a thickness of 28 μm was stuck to the photosensitive layer, and a photosensitive element including the support, the photosensitive layer, and the protective layer in this order was obtained.

### (Stacked Body)

A copper clad laminate (a substrate, manufactured by Showa Denko Materials Co., Ltd., product name “MCL-E67”) including a copper foil (Thickness: 35 μm) disposed on both surfaces of a glass epoxy material was washed with an acid and washed with water, and then, dried with an air flow. Next, the copper clad laminate was heated to 80° C., and then, the photosensitive element was laminated such that the photosensitive layer was in contact with the copper surface while peeling the protective layer to obtain a stacked body including the copper clad laminate, the photosensitive layer, and the support in this order. The lamination was performed at a crimping pressure of 0.4 MPa and a roll rate of 1.0 m/minute by using a heat roll at 110° C.

### (Sensitivity)

A 41-stage step tablet (manufactured by Showa Denko Materials Co., Ltd.) was placed on the support of the stacked body, and then, by a projection exposure machine (manufactured by Ushio Inc., product name “UX-2240SM”) using a super high-pressure mercury lamp (365 nm) as a light source, the photosensitive layer was exposed via the support in an exposure amount (an irradiation energy amount) at which the number of remaining steps of the 41-stage step tablet after developing was 11. On the basis of the exposure amount (Unit: mJ/cm²) in this case, a sensitivity was evaluated. It is indicated that the sensitivity is excellent as the exposure amount decreases.

### (Resolution and Cohesiveness)

A glass chromium type photo tool (Resolution Negative: including a wiring pattern having line width (L)/space width(S) (hereinafter, referred to as “L/S”) of 3x/x (x: 3 to 20, Unit: μm), Cohesiveness Negative: including a wiring pattern having line width/space width of x/3x (x: 3 to 20, Unit: μm)) was used on the support of the stacked body, and by a projection exposure machine (manufactured by Ushio Inc., product name “UX-2240SM”) using a super high-pressure mercury lamp (365 nm) as a light source, the photosensitive layer was exposed via the support in an exposure amount (an irradiation energy amount) at which the number of remaining steps of the 41-stage step tablet after developing was 11. After exposure, the support was peeled from the stacked body, the photosensitive layer was exposed, and 1.0% by mass of a sodium carbonate aqueous solution was sprayed at 30° C. for a time period twice the shortest developing time to remove an unexposed portion.

In the resolution negative, after the developing treatment, a resolution was evaluated on the basis of the minimum value among the space widths of a resist pattern in which a space portion (an unexposed portion) was removed without having a residue, and a line portion (an exposed portion) was formed without causing crooking and chipping. It is indicated that the resolution is excellent as the numerical value decreases.

In the cohesiveness negative, after the developing treatment, cohesiveness was evaluated on the basis of the minimum value among the line widths of the resist pattern in which the space portion (the unexposed portion) was removed without having a residue, and the line portion (the exposed portion) was formed without causing crooking and chipping. It is indicated that the cohesiveness is excellent as the numerical value decreases.

### (Breaking and Chipping Rate)

The photosensitive layer was exposed in the same procedure as that of the evaluation of the resolution and the cohesiveness described above, and then, the support was peeled from the stacked body, the photosensitive layer was exposed, and 1.0% by mass of a sodium carbonate aqueous solution was sprayed at 30° C. for a time period twice the shortest developing time to remove an unexposed portion. After developing, in a resist pattern having L/S of 10/10 μm, five lines with a length of 9 mm were observed, and a ratio of the length (mm) of a line with breakage and chip (such as breaking, chipping, and peeling) to the total line length (45 mm) was calculated as a breaking and chipping rate. A case where the line had the breakage and chip was evaluated as “A”, a case where the breaking and chipping rate was less than 20% was evaluated as “B”, and a case where the breaking and chipping rate was 20% or more was evaluated as “C”.

TABLE 2

| | | | | | Comparative | |
|---|---|---|---|---|---|---|
| | | Example | | | Example | |
| | | 1 | 2 | 3 | 1 | 2 |
| (A) | A1 | 55 | — | 54 | 57 | — |
| | A2 | — | 55 | — | — | — |
| | A3 | — | — | — | — | 55 |
| (B) | B1 | 45 | 45 | 43 | 28 | 45 |
| | B2 | — | — | — | — | — |
| | B3 | — | — | — | 10 | — |
| | B4 | — | — | — | — | — |
| | B5 | — | — | — | 5 | — |
| (C) | B-CIM | 3.5 | 3.5 | 3.5 | 2.9 | 3.5 |
| (D) | D1 | 0.04 | 0.04 | 0.04 | 0.08 | 0.04 |
| | D2 | — | — | — | — | — |
| | D3 | — | — | — | — | — |
| | D4 | — | — | — | — | — |
| (E) | E1 | 0.03 | 0.03 | 0.03 | 0.02 | 0.03 |
| | E2 | 0.01 | 0.01 | 0.01 | — | 0.01 |

| | | | | | |
|---|---|---|---|---|---|
| LCV | 0.7 | 0.7 | 0.7 | 0.3 | 0.7 |
| MKG | 0.05 | 0.05 | 0.05 | 0.05 | 0.05 |
| SF-808H | 1.0 | 1.0 | 1.0 | 1.0 | 1.0 |
| Sensitivity (mJ/cm²) | 80 | 80 | 80 | 65 | 80 |
| Cohesiveness x/3x | 6 | 7 | 7 | 9 | 9 |
| (μm) | | | | | |
| Resolution 3x/x | 5 | 4 | 4 | 5 | 8 |
| (μm) | | | | | |
| Breaking and | A | A | A | C | A |
| Chipping Rate | | | | | |

### Examples 4 to 8 and Comparative Examples 3 and 4

### (Photosensitive Resin Composition)

By mixing each component shown in Table 3 in a blending amount (parts by mass) shown in the same table, each photosensitive resin composition was prepared. Note that the blending amount (parts by mass) of the component (A) shown in Table 3 is the mass (the solid content) of a non-volatile content.

### (Photosensitive Element and Stacked Body)

A photosensitive element and a stacked body were produced by the same method as that in Examples 1 to 3, except that the photosensitive resin composition was applied onto the support such that the thickness of the photosensitive layer after drying was 15 μm.

### (Sensitivity)

A 41-stage step tablet (manufactured by Showa Denko Materials Co., Ltd.) was placed on the support of the stacked body, and then, by a direct writing exposure machine (manufactured by Via Mechanics, Ltd., product name “DE-1UH”) using a bruise blue laser diode with a wavelength of 405 nm as a light source, the photosensitive layer was exposed via the support in an exposure amount (an irradiation energy amount) at which the number of remaining steps of the 41-stage step tablet after developing was 15. On the basis of the exposure amount (Unit: mJ/cm²) in this case, a sensitivity was evaluated. It is indicated that the sensitivity is excellent as the exposure amount decreases.

### (Resolution)

A 41-stage step tablet (manufactured by Showa Denko Materials Co., Ltd.) was placed on the support of the stacked body, and then, by using a writing pattern having L/S of 3x/x (x=3 to 20, Unit: μm, an interval of 1 μm), exposure (writing) was performed on the photosensitive layer via the support in an exposure amount (an irradiation energy amount) at which the number of remaining steps of the 41-stage step tablet after developing was 15, by a direct writing exposure machine (manufactured by Via Mechanics, Ltd., product name “DE-1UH”) using a bruise blue laser diode with a wavelength of 405 nm as a light source.

After exposure, the support was peeled from the stacked body, the photosensitive layer was exposed, and 1.0% by mass of a sodium carbonate aqueous solution was sprayed at 30° C. for a time period twice the shortest developing time to remove an unexposed portion. After developing, a resolution was evaluated on the basis of the minimum value among the space widths of a resist pattern in which a space portion (an unexposed portion) was removed without having a residue, and a line portion (an exposed portion) was formed without causing crooking and chipping. It is indicated that the resolution is excellent as the numerical value decreases.

### (Cohesiveness)

The photosensitive layer was exposed and developed to remove the unexposed portion in the same procedure as that of the evaluation of the resolution described above, except that a writing pattern having L/S of x/3x (x=1 to 20, Unit: μm, an interval of 1 μm) was used. After developing, cohesiveness was evaluated on the basis of the minimum value among the line widths of the resist pattern in which the space portion (the unexposed portion) was removed without having a residue, and the line portion (the exposed portion) was formed without causing crooking and chipping. It is indicated that the cohesiveness is excellent as the numerical value decreases.

### (Breaking and Chipping Rate)

The photosensitive layer was exposed in the same procedure as that of the evaluation of the resolution and the cohesiveness described above, and then, the support was peeled from the stacked body, the photosensitive layer was exposed, and 1.0% by mass of a sodium carbonate aqueous solution was sprayed at 30° C. for a time period twice the shortest developing time to remove an unexposed portion. After developing, in a resist pattern having L/S of 5/5 μm, five lines with a length of 8 mm were observed, and a ratio of the length (mm) of a line with breakage and chip (such as breaking, chipping, and peeling) to the total line length (40 mm) was evaluated as a breaking and chipping rate. A case where the line had the breakage and chip was evaluated as “A”, a case where the breaking and chipping rate was less than 20% was evaluated as “B”, and a case where the breaking and chipping rate was 20% or more was evaluated as “C”.

TABLE 3

| | | | | | | | Comparative | |
|---|---|---|---|---|---|---|---|---|
| | | Example | | | | | Example | |
| | | 4 | 5 | 6 | 7 | 8 | 3 | 4 |
| (A) | A1 | — | — | — | — | — | — | — |
| | A2 | 56 | 56 | 56 | 56 | 56 | 56 | 56 |
| | A3 | — | — | — | — | — | — | — |
| (B) | B1 | 44 | 24 | — | 44 | 44 | 35 | 35 |
| | B2 | — | 20 | 44 | — | — | — | — |
| | B3 | — | — | — | — | — | — | — |
| | B4 | — | — | — | — | — | 5 | 5 |
| | B5 | — | — | — | — | — | 4 | 4 |
| (C) | B-CIM | 6.5 | 6.5 | 6.5 | 6.5 | 6.5 | 6.0 | 8.0 |
| (D) | D1 | — | — | — | — | — | — | — |
| | D2 | 0.65 | 0.65 | 0.65 | — | — | 0.65 | 0.65 |
| | D3 | — | — | — | 0.65 | — | — | — |
| | D4 | — | — | — | — | 0.65 | — | — |
| (E) | E1 | 0.02 | 0.02 | 0.02 | 0.02 | 0.02 | 0.02 | 0.02 |
| | E2 | 0.03 | 0.03 | 0.03 | 0.03 | 0.03 | 0.01 | 0.01 |

| | | | | | | | |
|---|---|---|---|---|---|---|---|
| LCV | 0.4 | 0.4 | 0.4 | 0.4 | 0.4 | 0.5 | 0.5 |
| MKG | 0.02 | 0.02 | 0.02 | 0.02 | 0.02 | 0.02 | 0.02 |
| SF-808H | 0.5 | 0.5 | 0.5 | 0.5 | 0.5 | 0.5 | 0.5 |
| Sensitivity | 140 | 140 | 140 | 130 | 135 | 100 | 120 |
| (mJ/cm²) | | | | | | | |
| Cohesiveness x/3x | 4 | 4 | 4 | 4 | 4 | 5 | 5 |
| (μm) | | | | | | | |
| Resolution 3x/x | 10 | 10 | 10 | 8 | 8 | 12 | 10 |
| (μm) | | | | | | | |
| Breaking and | A | A | A | A | A | B | B |
| Chipping Rate | | | | | | | |

### REFERENCE SIGNS LIST

1: photosensitive element, 2, 20: support, 3, 30: photosensitive layer, 4: protective layer, 32: resist pattern, 40: conductor layer, 42: conductor layer after etching treatment, 50: insulating layer, 60: plating layer, 62: plating layer after etching treatment, 70: conductor pattern, 80: active ray.

1. A photosensitive resin composition, comprising a binder polymer, a photopolymerizable compound, a photopolymerization initiator, and a sensitizer,
wherein the binder polymer includes a polymer having a styrene compound and aryl (meth)acrylate as a monomer unit, and
the photopolymerizable compound includes a polyfunctional monomer having two or more reactive groups causing a reaction by radicals and 8 to 16 oxyethylene groups, and a content of the polyfunctional monomer is 96% by mass or more, on the basis of a total amount of the photopolymerizable compound.

2. The photosensitive resin composition according to claim 1, wherein a molecular weight of the polyfunctional monomer is 600 to 1200.

3. The photosensitive resin composition according to claim 1, wherein the polyfunctional monomer further has a bisphenol A skeleton or a ditrimethylol propane skeleton.

4. The photosensitive resin composition according to claim 1, wherein the binder polymer further has hydroxyalkyl (meth)acrylate as a monomer unit.

5. The photosensitive resin composition according to claim 1, wherein the sensitizer includes a dialkyl aminobenzophenone compound or an anthracene compound.

6. A photosensitive element, comprising;
a support; and
a photosensitive layer formed on the support by using the photosensitive resin composition according to claim 1.

7. A method for producing a wiring board, comprising:
a step of providing a photosensitive layer on a substrate by using the photosensitive resin composition according to claim 1;
a step of photocuring a part of the photosensitive layer;
a step of removing an uncured portion of the photosensitive layer to form a resist pattern; and
a step of forming a wiring layer in a portion of the substrate in which the resist pattern is not formed.

8. A method for producing a wiring board, comprising:
a step of providing a photosensitive layer on a substrate by using the photosensitive element according to claim 6;
a step of photocuring a part of the photosensitive layer;
a step of removing an uncured portion of the photosensitive layer to form a resist pattern; and
a step of forming a wiring layer in a portion of the substrate in which the resist pattern is not formed.
